(19) United States
(12) Patent Application Publication
(10) Pub. No.: US 2015/0130025 A1
(43) Pub. Date: May 14, 2015

(54) TRANSISTOR FABRICATING METHOD AND TRANSISTOR

(71) Applicants: PEKING UNIVERSITY FOUNDER GROUP CO., LTD., Beijing (CN); FOUNDER MICROELECTRONICS INTERNATIONAL CO., LTD., Guangdong Province (CN)

(72) Inventors: Guangran PAN, Guangdong Province (CN); Yan WEN, Guangdong Province (CN); Kun WANG, Guangdong Province (CN)

(21) Appl. No.: 14/536,841

(22) Filed: Nov. 10, 2014

(30) Foreign Application Priority Data
Nov. 14, 2013 (CN) 201310567397.8

(51) Int. Cl. H01L 29/732; H01L 29/08; H01L 21/311; H01L 21/324; H01L 21/225; H01L 21/283; H01L 29/66; H01L 29/10

(52) U.S. Cl. CPC H01L 29/7322; H01L 29/66272; H01L 29/0804; H01L 29/1004; H01L 21/324; H01L 21/2253; H01L 21/283; H01L 21/31144
USPC 257/587; 438/369

(57) ABSTRACT

The invention provides a method for fabricating a transistor and a transistor, wherein the method for fabricating a transistor includes: growing a second oxide layer on the surface of a substrate on which a first oxide layer and a first base region are formed, wherein the second oxide layer is formed above the first base region; forming an emitter region in a first preset area on the second oxide layer; forming a contact hole in a second preset area on the second oxide layer, wherein the second preset area does not overlap with the first preset area; injecting doping elements into the surface of the first base region in the area of the contact hole; and thermally processing the substrate to activate the doping elements to form a second base region. The invention may fabricate the dense base region lithography layer and the contact hole lithography layer in an integrate process ingeniously to thereby perform self-alignment between the dense base region lithography layer and the contact hole lithography layer and address the problem deviation of alignment between the dense base area and the contact hole.

The present application claims priority to Chinese Patent Application No. 201310567397.8, filed with the State Intellectual Property Office of China on Nov. 14, 2013 and entitled “Transistor fabricating method and transistor”, which is hereby incorporated by reference in its entirety.

### FIELD OF THE INVENTION

The present invention relates to the field of fabricating a semiconductor device and particularly to a transistor fabricating method and a transistor fabricated by using the transistor fabricating method.

### BACKGROUND OF THE INVENTION

Radio frequency transistors are increasingly used along with the development of radio frequency and wireless communication technologies. Broadly radio frequency transistors include radio frequency bi-polar transistors and radio frequency field effect transistors, and narrowly radio frequency transistors particularly refer to radio frequency bi-polar transistors (RF bipolar transistors, wherein a “radio frequency transistor” below particularly refers to a radio frequency bipolar transistor).

The most important parameter to evaluate the performance of a radio frequency transistor is its operating frequency, and in order to improve the operating frequency of the radio frequency transistor, both a comb-like strip-shaped structure with small lines and a poly-silicon emitter structure are generally adopted in practical processes.

FIG. 1 is a schematic structural diagram of a transistor in a sectional view, wherein the transistor includes a collector region, a base region and an emitter region; the collector region includes an N-type epitaxy and an N-type substrate; and the emitter region includes poly-silicon and an N-type diffusion region, wherein the N-type diffusion region is formed by thermally diffusing doping elements (phosphor or arsenic) in the poly-silicon to the surface of the base region in a high temperature environment. In order to improve the operating frequency, a dense base region is fabricated in the base region outside the emitter region to lower the resistance in the base region, and in a practical process, the dense base region is spaced from the emitter region by some distance (illustrated as S in the figure) in order to prevent them from being shorted. The area where the base region and the dense base region are located is an active region, wherein the surface of the active region is covered with a thin oxide layer, and the area outside the active region (referred to as a field region) is covered with a thick oxide layer (also referred to as a field oxide layer). The collector region, the base region and the emitter region correspond respectively to three metal electrodes which a collector electrode, a base and an emitter, wherein the collector electrode extends outward from the N-type substrate, i.e., the back face of a chip (not illustrated in the figure), the emitter extends outward from metal on the surface of the poly-silicon, the base extends out from metal on the surface of the dense base region through a contact hole which is an opening of the oxide layer above the dense base region, and in order to ensure the resistance of the contact hole to be sufficiently small, the width of the dense base region has to be larger than or equal to the width of the contact hole (illustrated as d1 in FIG. 1); otherwise, the contact hole is offset above the base region. The doping concentration of the base region is lower, and the resistance of the contact hole is higher.

Relevant terms will be briefly explained below. All the processes of fabricating a semiconductor device are performed on a wafer which is a rounded semiconductor substrate (the material of the substrate is mono-crystalline silicon, germanium, germanium-silicon, etc., and the diameter of the substrate is 3 inches, 4 inches, 5 inches, 6 inches, 8 inches or 12 inches). In a process of fabricating a wafer of an integrated circuit, several, more than ten or tens of lithography processes are required, and in these lithography processes (and ion injection, etching and other processes after the lithography processes), patterns on masks are duplicated one by one onto the wafer, and in the art of semiconductors, generally “a” lithography process is referred to as “a layer of” lithography process, and a lithography process and the ion injection, etching and other processes after the lithography process are referred collectively to as a “lithography layer”. A core device of a lithography process is a lithography machine.

In a lithography process, the precision of alignment between layers is of great importance. An ideal value of deviation of alignment between layers is 0, but a certain amount of deviation of alignment will arise in practice, and when deviation of alignment exceeding a rated specification arises in any layer of lithography process, the entire chip will be invalid. An alignment operation in the lithography process is performed upon collecting, by the lithography machine, coordinates of an optical mark which is referred to as an “alignment mark”, wherein the alignment mark is an optical mark, with a stepped section, reserved and fabricated on a preset location of coordinates on the wafer in a lithography process before the current layer of lithography process (referred to as a “previous layer of lithography process”) and etching, oxidization and other processes after the lithography process.

In the traditional method, the transistor is fabricated in the following process:

1. The thick oxide layer and the base region are fabricated, wherein the thick oxide layer (the field oxide layer) and the base region are formed respectively in preset areas on the surface of the N-type substrate, on which an N-type epitaxy section is grown, by lithography, etching, oxidation, ion injection and other processes, to form a semi-finished product as illustrated in FIG. 2, wherein the area covered with the thick oxide layer is the field region, the area outside the field region is the active region, and the base region is the area where the active region is located. The lithography layer at which the thick oxide layer is formed is referred to as an active region lithography layer, and the lithography layer at which the base region is formed is referred to as a base region lithography layer.

2. The dense base region is fabricated, wherein the dense base is formed in a preset area through lithography, ion injection, annealing and other processes, as illustrated in FIG. 3. The lithography layer at which the dense base region is formed is referred to as a dense base region lithography layer.

3. The thin oxide layer is fabricated, wherein as illustrated in FIG. 4, the thin oxide layer is grown on the surface of the structure illustrated in FIG. 3.

4. The poly-silicon emitter is fabricated, wherein an oxide layer opening (referred to as an emitter region opening) is formed in a preset area through lithography, etching and other processes, and then the poly-silicon is grown and doped, and then the poly-silicon emitter is formed in the area of the oxide layer opening through lithography, etching and other processes. As described above, the emitter region has to be spaced from the dense base region by a preset distance, as illustrated in FIG. 5, wherein the distance between them is denoted as S. The lithography layer at which the emitter region opening is formed is referred to as an emitter lithography layer, and the lithography layer at which the poly-silicon emitter is formed is referred to as a poly-silicon lithography layer.

5. The structure formed above is thermally processed at high temperature to activate the doping elements in the poly-silicon, to thereby thermally diffuse them to the surface of the base region to form an N-type diffusion region, as illustrated in FIG. 6.

6. The contact hole is fabricated, wherein an oxide layer opening (i.e., the contact hole) is formed in a preset area through lithography, etching and other processes. As described above, the width of the dense base region has to be larger than or equal to the width of the contact hole, wherein the width of the dense base region is larger than the width of the contact hole (by a distance of d1 on a side) as illustrated in FIG. 7. The lithography layer at which the contact hole is formed is referred to as a contact hole lithography layer.

7. The metal electrodes are fabricated, wherein the emitter electrode and the base region electrode are formed in preset area through metal deposition, lithography, etching and other processes, as illustrated in FIG. 8. The lithography layer at which the metal electrodes are formed is referred to as a metal lithography layer.

So far the general device structure of the radio frequency transistor has been completed, and subsequent processes including fabrication of a passivation protection layer and the collector metal electrode on the back face and other processes are common processes in the art, so a repeated description thereof will be omitted here.

The traditional method above for fabricating a transistor has the following drawbacks:

1. There are a number layers of lithography process, wherein the dense base region has to be fabricated in a separate lithography layer process (in the operation 2 above), thus making the process costly;

2. The width of the dense base region of the transistor has to be larger than or equal to the width of the contact hole, and in the traditional method above, the dense base region and the contact hole are fabricated at different lithography layers between which a certain quantity of deviation of alignment will arise, and in order to ensure that the contact hole will not be offset outside the area, wherein the dense base region is located, even if there is lithography deviation of alignment, the width of the dense base region has to be made sufficiently larger than the width of the contact hole in the design of the chip (denoted as d1 illustrated in FIG. 7 in the operation 6 above), thus making the area of the chip larger and the cost thereof higher.

3. The emitter region and the dense base region of the transistor have to be spaced at a preset distance, and in the traditional method above, the dense base region lithography layer and the emitter region lithography layer are different lithography layers and aligned by aligning the alignment mark reserved at the active region lithography layer, that is, the dense base region lithography layer and the emitter region lithography layer are aligned indirectly instead of being aligned directly (being aligned directly refers to that the two layers are an alignment layer and an aligned layer). The dense base region lithography layer is fabricated before the emitter region lithography layer, but the dense base region lithography layer is doped through ion injection only in the preset area without involving any process in which a stepped alignment mark may be fabricated, so no alignment mark may be reserved and fabricated at the dense base region lithography layer, that is, the emitter region lithography has to be performed through alignment with the alignment mark reserved at the active region lithography layer for the purpose of alignment.

Since deviation of alignment between such indirectly aligned layers is more difficult to control than in direct alignment, in order to ensure a guard distance to be maintained between the emitter region and the dense base region even if there is considerable deviation of alignment (so as to prevent them from being shorted), the preset distance between the emitter region and the dense base region has to be made sufficiently large in the design of the chip, thus making the area of the chip larger and the cost thereof higher.

### SUMMARY OF THE INVENTION

In view of at least one of the problems above, the present invention provides a method for fabricating a transistor by which the dense base region lithography layer and the contact hole lithography layer may be fabricated in an integrated process to thereby lower the number of lithography layers, avoid indirect alignment between the dense base region lithography layer and the emitter region lithography layer, lower deviation of alignment and save the area of the chip.

An aspect of the present invention provides a method for fabricating a transistor, which includes: growing a second oxide layer on the surface of a substrate on which a first oxide layer and a first base region are formed, wherein the second oxide layer is formed above the first base region; forming an emitter region in a first preset area on the second oxide layer; forming a contact hole in a second preset area on the second oxide layer, wherein the second preset area does not overlap with the first preset area; injecting doping elements into the surface of the first base region in the area of the contact hole; and thermally processing the substrate to activate the doping elements and form a second base region (a dense base region).

In the method for fabricating a transistor according to the embodiment of the present invention, the contact hole is formed, and then the doping elements are injected into the area of the contact hole to form the dense base region. In this process, there is only a lithography layer at which the contact hole is formed but no lithography layer at which the dense base region is formed, thus saving a process of forming a dense base region lithography layer and lowering the cost of the process.

Since the dense base region and the contact hole are fabricated at the same lithography layer, a problem of deviation of alignment between them is solved, so there is no need to make the width of the dense base region sufficiently larger than the width of the contact hole in the design of a chip as done in the traditional method, thus saving the area of the chip and lowering the cost thereof.

Moreover, the contact hole lithography layer is fabricated after the emitter lithography layer, and the dense base region (i.e., contact hole lithography) may be fabricated by aligning an alignment mark reserved and fabricated at the emitter region lithography layer for the purpose of alignment, that is, direct alignment between the dense base region lithography layer and the emitter region lithography layer is achieved, the precision of direct alignment is higher than the precision of indirect alignment in the traditional method, so that a smaller distance between the emitter region and the dense base region may be set in the design of the chip to thereby save the area of the chip and lower the cost thereof.

Another aspect of the present invention further provides a transistor fabricated by using the method for fabricating a lithography described in the above technical solution.

### BRIEF DESCRIPTION OF THE DRAWINGS

FIG. 1 illustrates a schematic structural diagram in a sectional view of the transistor in the prior art;

FIG. 2 illustrates a schematic structural diagram in a sectional view of the semi-finished product after the thick oxide layer and the base region are formed in the prior art;

FIG. 3 illustrates a schematic structural diagram in a sectional view of the transistor after the dense base region is formed in the prior art;

FIG. 4 illustrates a schematic structural diagram in a sectional view of the transistor after the thin oxide layer is formed in the prior art;

FIG. 5 illustrates a schematic structural diagram in a sectional view of the transistor after the poly-silicon emitter is formed in the prior art;

FIG. 6 illustrates a schematic structural diagram in a sectional view of the transistor after thermal processing at high temperature in the prior art;

FIG. 7 illustrates a schematic structural diagram in a sectional view of the transistor after the contact hole is formed in the prior art;

FIG. 8 illustrates a schematic structural diagram in a sectional view of the transistor after the metal electrodes are formed in the prior art;

FIG. 9 illustrates a flow chart of a method for fabricating a transistor according to an embodiment of the present invention;

FIG. 10 illustrates a schematic structural diagram in a sectional view of the transistor after a thin oxide layer is formed according to the embodiment of the present invention;

FIG. 11 illustrates a schematic structural diagram in a sectional view of the transistor after a poly-silicon emitter is formed according to the embodiment of the present invention;

FIG. 12 illustrates a schematic structural diagram in a sectional view of the transistor after contact hole lithography is performed according to the embodiment of the present invention;

FIG. 13 illustrates a schematic structural diagram in a sectional view of the transistor after a contact hole is formed and boron ion injection is performed according to the embodiment of the present invention;

FIG. 14 illustrates a schematic structural diagram in a sectional view of the transistor after thermal processing at high temperature according to the embodiment of the present invention; and

FIG. 15 illustrates a schematic structural diagram in a sectional view of the transistor after metal electrodes are formed according to the embodiment of the present invention.

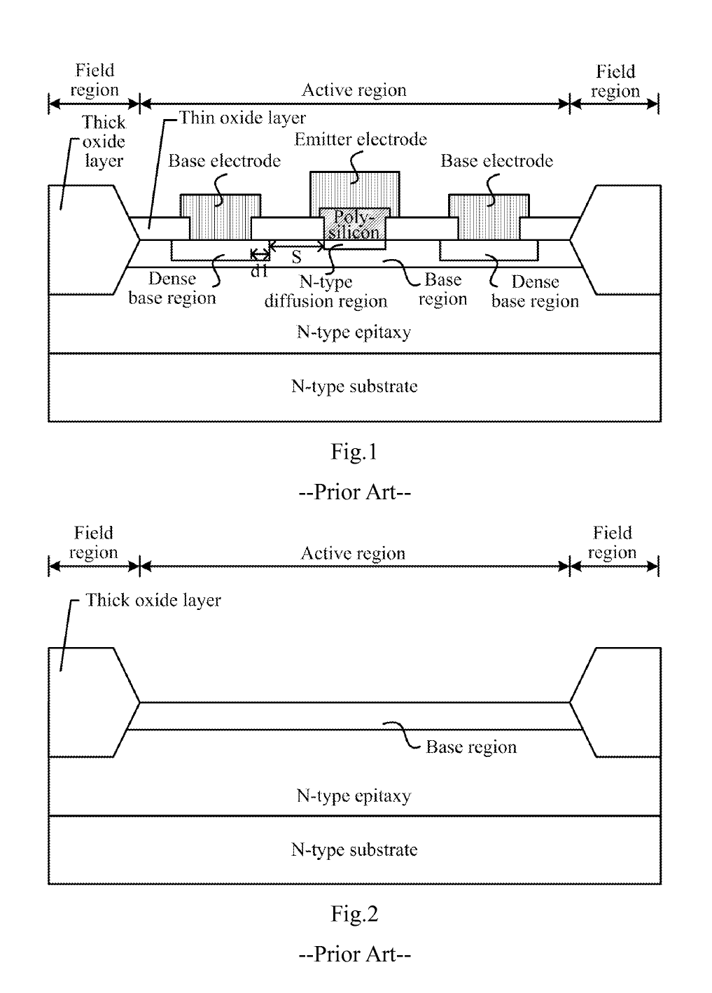

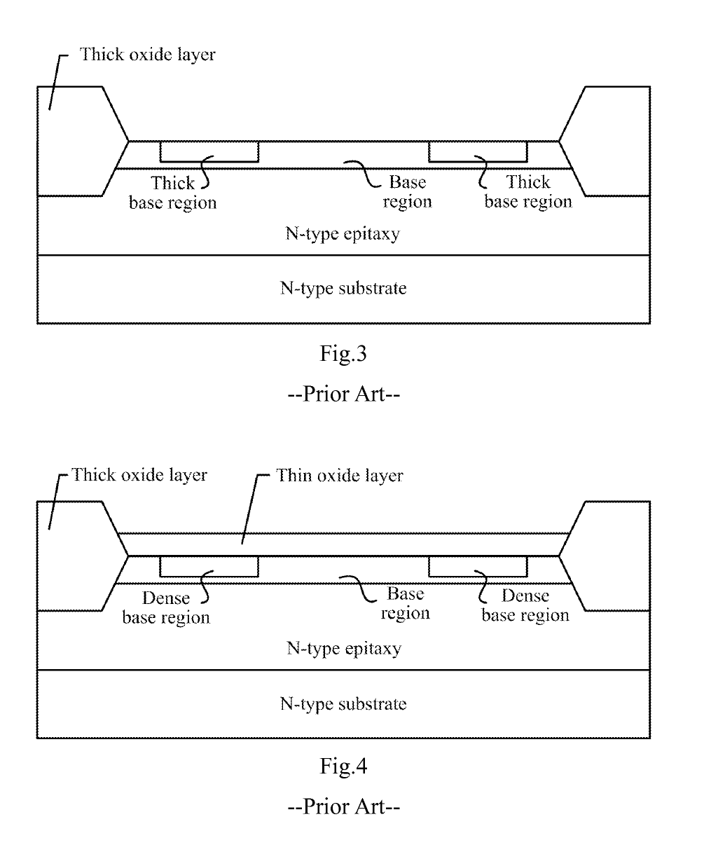

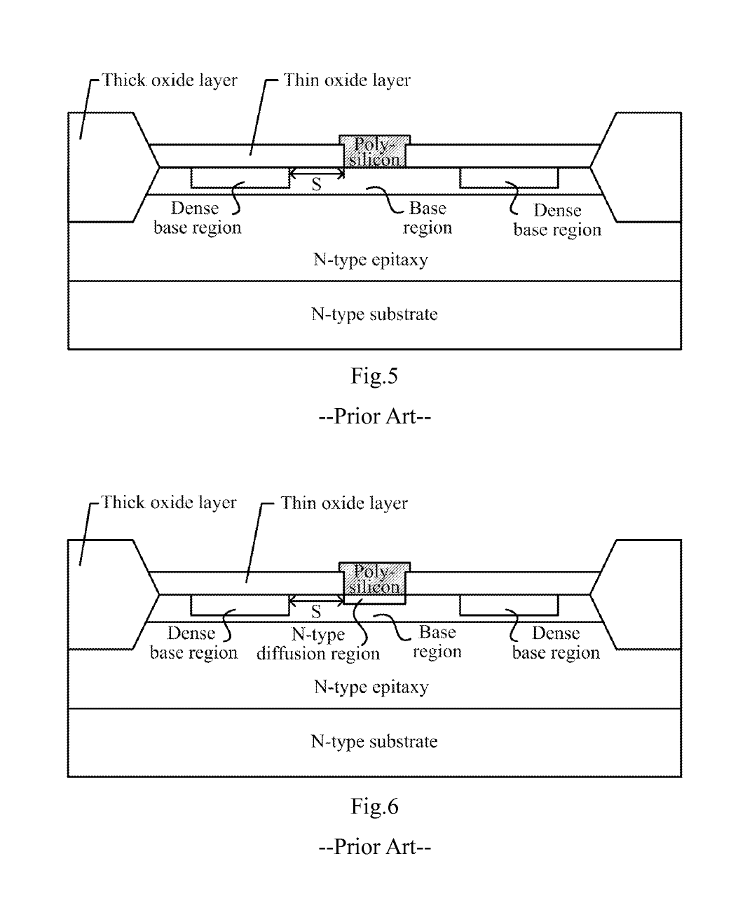

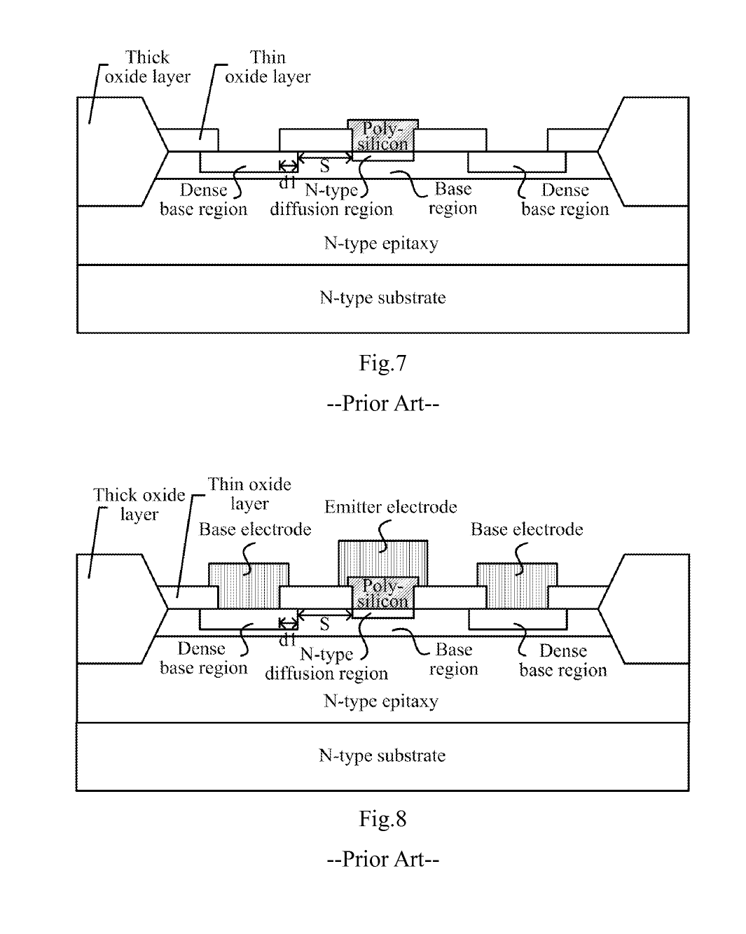

### DETAILED DESCRIPTION OF THE EMBODIMENTS

In order to make the foregoing objects, features and advantages of the present invention more apparent, the present invention will be described further in detail below, with reference to the drawings and particular embodiments thereof. It shall be noted that the embodiments of the present invention and features in the embodiments may be combined with each other unless there is confliction between them.

Numerous particular details will be set forth in the following description for sufficient understanding of the present invention, but the present invention may also be embodied in other implementations than those described here, so the scope of the present invention will not be limited to the particular embodiments described below.

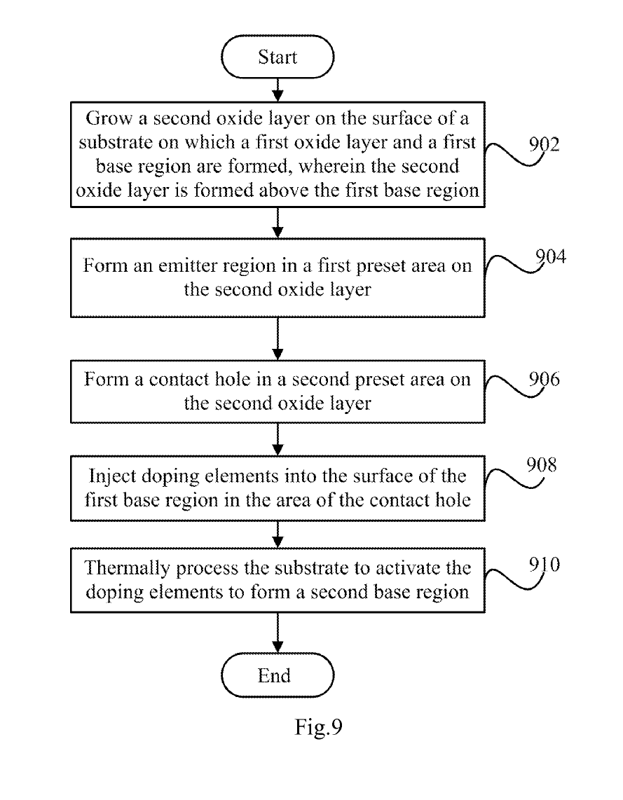

FIG. 9 illustrates a flow chart of a method for fabricating a transistor according to an embodiment of the present invention.

As illustrated in FIG. 9, the method for fabricating a transistor according to the embodiment of the present invention may include the following operations:

The operation 902 is to grow a second oxide layer on the surface of a substrate on which a first oxide layer and a first base region are formed, wherein the second oxide layer is formed above the first base region;

The operation 904 is to form an emitter region in a first preset area on the second oxide layer;

The operation 906 is to form a contact hole in a second preset area on the second oxide layer, wherein the second preset area does not overlap with the first preset area;

The operation 908 is to inject doping elements into the surface of the first base region in the area of the contact hole; and

The operation 910 is to thermally process the substrate to activate the doping elements to form a second base region.

In the method for fabricating a transistor according to the embodiment of the present invention, the contact hole is formed, and then the doping elements are injected into the area of the contact hole to form the dense base region. In this process, there is only a lithography layer at which the contact hole is formed but no lithography layer at which the dense base region is formed, thus saving a process of forming a dense base region lithography layer and lowering the cost of the process.

Since the dense base region and the contact hole are fabricated at the same lithography layer, a problem of deviation of alignment between them is solved, so there is no need to make the width of the dense base region sufficiently larger than the width of the contact hole in the design of a chip as done in the traditional method, thus saving the area of the chip and lowering the cost thereof.

Moreover the contact hole lithography layer is fabricated after the emitter lithography layer, and the dense base region (i.e., contact hole lithography) may be fabricated by aligning an alignment mark reserved and fabricated at the emitter region lithography layer for the purpose of alignment, that is, direct alignment between the dense base region lithography layer and the emitter region lithography layer is achieved, the precision of direct alignment is higher than the precision of indirect alignment in the traditional method, so that a smaller distance between the emitter region and the dense base region may be set in the design of the chip to thereby save the area of the chip and lower the cost thereof.

In the technical solution above, preferably the operation of forming the contact hole in the second preset area on the second oxide layer may particularly include: coating photo-resist on the surface of the substrate on which the first oxide layer, the first base region, the second oxide layer and the emitter region are formed; removing the photo-resist in the second preset area on the second oxide layer to form a photo-resist opening in the second preset area; and etching the second oxide layer in the area of the photo-resist opening to form the contact hole.

In the technical solution above, preferably after the doping elements are injected into the surface of the first base region in the area of the contact hole and before the substrate is thermally processed, the method further includes: removing the remaining photo-resist with which the surface of the semi-finished product of the transistor is covered.

In the technical solution above, preferably the second oxide layer with a preset thickness is reserved between the bottom of the contact hole and the first base region.

In order to alleviate a damage of the etching and ion injection processes to the base region, a small amount of the oxide layer may be reserved at the bottom of the contact hole.

In the technical solution above, preferably, the preset thickness ranges from 200 to 500 angstroms.

In the technical solution above, preferably after the substrate is thermally processed, the method may further include: washing off the second oxide layer with the preset thickness at the bottom of the contact hole by using hydrofluoric acid solution. The silicon oxide layer remaining at the bottom of the contact hole may be removed by using chemical solution to thereby alleviate a damage of drying etching to the surface of the base region.

In the technical solution above, preferably after the second oxide layer with the preset thickness at the bottom of the contact hole is washed off by using the hydrofluoric acid solution, the method may further include: fabricating metal electrodes respectively on the second base region and on the emitter region.

In the technical solution above, preferably the thickness of the second oxide layer is smaller than the thickness of the first oxide layer.

The transistor according to an embodiment of the present invention is a transistor fabricated through the method for fabricating a transistor described in the above technical solution.

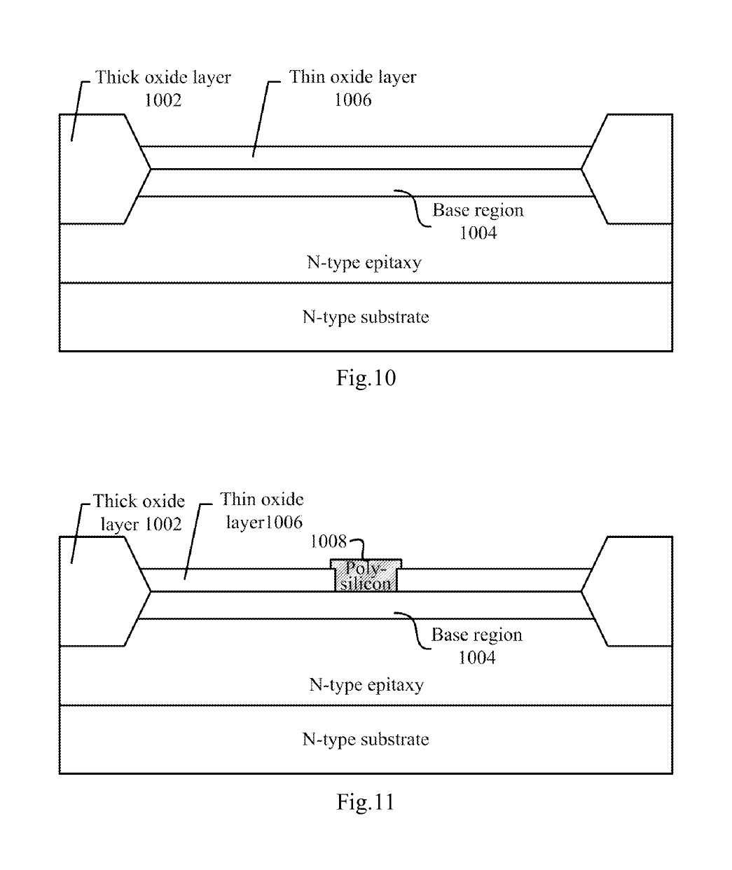

Another embodiment of the present invention will be further described below with reference to FIG. 10 to FIG. 15.

A method for fabricating a transistor according to an embodiment of the present invention may include the following processes:

A thin oxide layer (i.e., a second oxide layer) 1006 is grown on the surface of a semiconductor substrate on which an N-type substrate, an N-type epitaxy, a thick oxide layer (a field oxide layer, i.e., a first oxide layer) 1002 and a base region (i.e., a first base region) 1004 are formed, as illustrated in FIG. 10.

In the semi-finished product of the transistor including the N-type substrate, the N-type epitaxy, the thick oxide layer (the field oxide layer) and the base region, the area of the semi-finished product covered by the thick oxide layer is a field region, and the area except the field region is an active region, and the base region is located in the area where the active region is located, and the thickness of the thick oxide layer ranges from 5000 to 30000 angstroms. The thickness of the thin oxide layer ranges from 1000 to 4000 angstroms.

As illustrated in FIG. 11, an emitter region opening is formed in a preset area on the thin oxide layer 1006, and then a poly-silicon emitter 1008 is formed in the area of the emitter region opening, wherein the poly-silicon emitter 1008 is doped with impurity elements of phosphor or arsenic. A particular process in this operation is the same as the operation 4 in the traditional method described in the Background of the Invention, so a repeated description thereof will be omitted here.

Then a contact hole lithography is performed to form a photo-resist opening in a preset area on the surface of the thin oxide layer, particularly as follows:

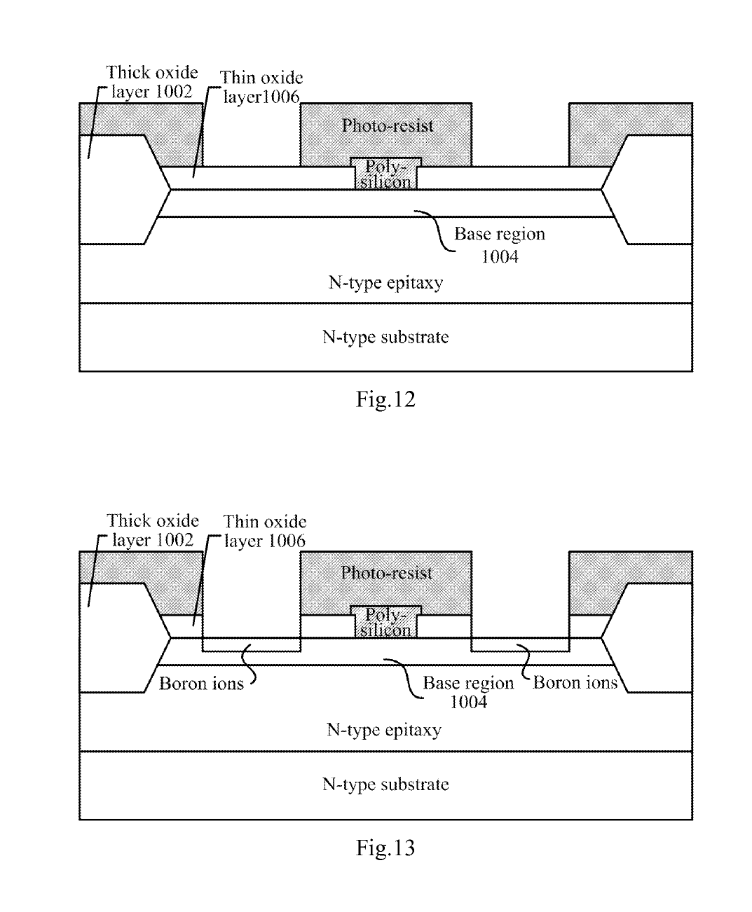

As illustrated in FIG. 12, photo-resist is coated on the surface of the structure illustrated in FIG. 11, and then the photo-resist in the preset area on the surface of the thin oxide layer is removed through lithography to form the photo-resist opening to expose the think oxide layer in the preset area while reserving the photo-resist in the area except the preset area.

The thin oxide layer in the area of the photo-resist opening is removed through etching to form an oxide layer opening (i.e., a contact hole), and boron ions are injected in the base region in the area of the photo-resist opening, as illustrated in FIG. 13.

In the course of etching the thin oxide layer in the area where the photo-resist opening is located, the thin oxide layer in the area of the photo-resist opening is etched by using downward vertical plasma dry etching until the remaining thickness of the thin oxide layer is below a preset value (preferably about 200 angstrom, that is, the oxide layer opening at the bottom of which a small amount of the thin oxide layer remains is formed), and then the remaining thin oxide layer is penetrated through ion injection to inject boron ions into the base region in the area of the photo-resist opening, and then the thin oxide layer remaining in the area of the photo-resist opening is washed using chemical etchant. This process may lower a damage of the etching and ion injection processes to the surface of the base region. Those skilled in the art shall appreciate that the small amount of the thin oxide layer may not be reserved at the bottom of the contact hole.

Preferably, the injection dose of the boron ions ranges from 1E15 to 1E16 atoms/square centimeters and the injection energy thereof ranges from 15 to 300 kilo-electro volts.

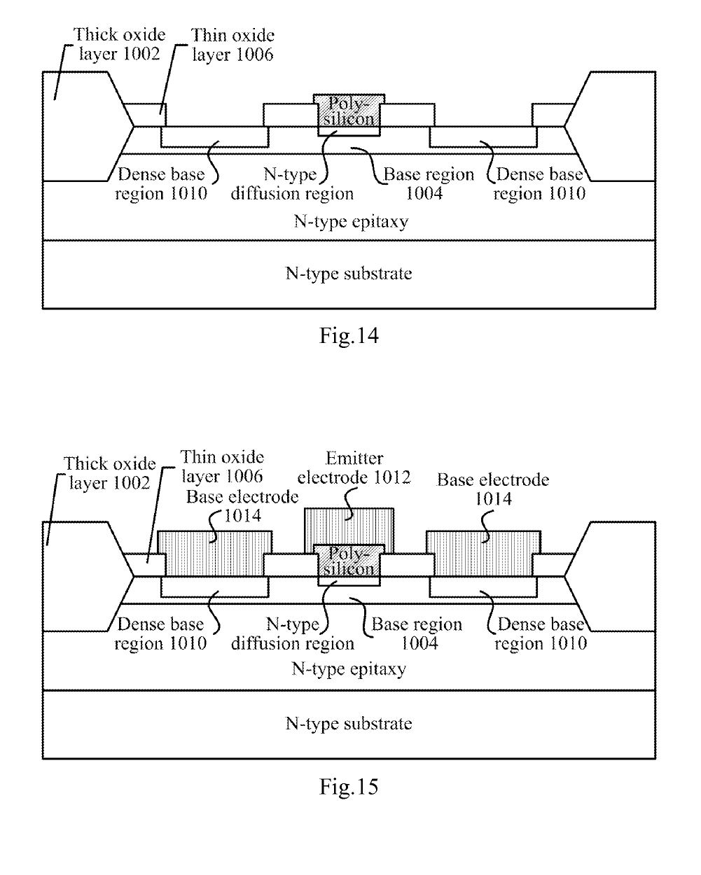

Next as illustrated in FIG. 14, the photo-resist is removed, and then the semiconductor substrate is thermally processed at high temperature so that the boron ions injected into the base region in the previous operation are activated and thermally diffused to form a dense base region (a second base region) 1010 and also the doped elements (phosphor or arsenic) in the poly-silicon are activated and thermally diffused to the surface of the base region form an N-type diffusion region.

As illustrated in FIG. 15, metal electrodes are fabricated. This operation is the same as in the traditional method, that is, an emitter electrode 1012 and a base region electrode 1014 are formed in a preset area through metal deposition, lithography, etching and other processes.

So far the major structure of the transistor has been finished, and subsequent processes including fabrication of a passivation protection layer and the collector metal electrode on the back face and other processes are common processes in the prior art, so a repeated description thereof will be omitted here.

With the process flow above, in the method for fabricating a transistor according to the present invention, the dense base region lithography layer and the contact hole lithography layer are fabricated in an integrated process ingeniously, and in the present invention, both of them are integrated at the same lithography layer, that is, the contact hole lithography layer also is the dense base region lithography layer, to thereby reduce one lithography layer so as to lower the cost of the process.

Moreover, in the present invention, since the dense base region and the contact hole are fabricated at the same lithography layer, a problem of deviation of alignment between them is solved, so there is no need to make the width of the dense base region sufficiently larger than the width of the contact hole in the design of a chip as done in the traditional method, thus saving the area of the chip and lowering the cost thereof.

Moreover in the present invention, the dense base region lithography layer (i.e., the contact hole lithography layer) is fabricated after the emitter lithography layer, and the dense base region lithography (i.e., the contact hole lithography) may be performed by aligning an alignment mark reserved and fabricated at the emitter region lithography layer for the purpose of alignment, that is, direct alignment between the dense base region lithography layer and the emitter region lithography layer is achieved, the precision of direct alignment is higher than the precision of indirect alignment in the traditional method, so that a smaller distance between the emitter region and the dense base region may be set in the design of the chip to thereby save the area of the chip and lower the cost thereof.

Although the preferred embodiments of the present invention have been described, those skilled in the art benefiting from the underlying inventive concept may make additional modifications and variations to these embodiments. Therefore, the appended claims are intended to be construed as encompassing the preferred embodiments and all the modifications and variations coming into the scope of the present invention.

Evidently, those skilled in the art can make various modifications and variations to the present invention without departing from the scope of the present invention. Thus the present invention is also intended to encompass these modifications and variations thereto so long as the modifications and variations come into the scope of the claims appended to the present invention and their equivalents.

1. A method for fabricating a transistor, comprising:
growing a second oxide layer on a surface of a substrate on which a first oxide layer and a first base region are formed, wherein the second oxide layer is formed above the first base region;
forming an emitter region in a first preset area on the second oxide layer;
forming a contact hole in a second preset area on the second oxide layer, wherein the second preset area does not overlap with the first preset area;
injecting doping elements into the surface of the first base region in an area of the contact hole; and
thermally processing the substrate to activate the doping elements to form a second base region.

2. The method for fabricating a transistor according to claim 1, wherein the operation of forming the contact hole in the second preset area on the second oxide layer particularly comprises:
coating photo-resist on the surface of the substrate on which the first oxide layer, the first base region, the second oxide layer and the emitter region are formed;
removing the photo-resist in the second preset area on the second oxide layer to form a photo-resist opening in the second preset area; and
etching the second oxide layer in an area of the photo-resist opening to form the contact hole.

3. The method for fabricating a transistor according to claim 2, wherein after the doping elements are injected into the surface of the first base region in the area of the contact hole and before the substrate is thermally processed, the method further comprises
removing remaining photo-resist with which the surface of the substrate is covered.

4. The method for fabricating a transistor according to claim 1, wherein the second oxide layer with a preset thickness is reserved between bottom of the contact hole and the first base region.

5. The method for fabricating a transistor according to claim 4, wherein the preset thickness ranges from 200 to 500 angstroms.

6. The method for fabricating a transistor according to claim 4, wherein after the substrate is thermally processed, the method further comprises:
washing off the second oxide layer with the preset thickness at bottom of the contact hole by using hydrofluoric acid solution.

7. The method for fabricating a transistor according to claim 6, wherein after the second oxide layer with the preset thickness at the bottom of the contact hole is washed off by using the hydrofluoric acid solution, the method further comprises:
fabricating metal electrodes respectively on the second base region and on the emitter region.

8. The method for fabricating a transistor according to claim 1, wherein the thickness of the second oxide is smaller than the thickness of the first oxide layer.

9. The method for fabricating a transistor according to claim 1, wherein the doping elements are boron elements.

10. A transistor, fabricated through a method for fabricating a transistor, wherein the method comprises:
growing a second oxide layer on a surface of a substrate on which a first oxide layer and a first base region are formed, wherein the second oxide layer is formed above the first base region;
forming an emitter region in a first preset area on the second oxide layer;
forming a contact hole in a second preset area on the second oxide layer, wherein the second preset area does not overlap with the first preset area;
injecting doping elements into the surface of the first base region in an area of the contact hole; and
thermally processing the substrate to activate the doping elements to form a second base region.
